(19) United States
(12) Patent Application Publication
(10) Pub. No.: US 2008/0116443 A1
(43) Pub. Date: May 22, 2008

(54) PHASE CHANGE MEMORY DEVICE WITH HOLE FOR A LOWER ELECTRODE DEFINED IN A STABLE MANNER AND METHOD FOR MANUFACTURING THE SAME

(76) Inventors: Heon Yong CHANG, Gyeonggi-do (KR); Suk Kyoung HONG, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 11/854,898

(22) Filed: Sep. 13, 2007

(30) Foreign Application Priority Data
Nov. 16, 2006 (KR) 10-2006-0113471

(51) Int. Cl. H01L 47/00; H01L 21/00

(52) U.S. Cl. 257/4; 438/482; 257/E47.001; 257/E21.09

(57) ABSTRACT

A phase change memory device is manufactured by forming a first insulation layer on a semiconductor substrate having a plurality of phase change cell forming regions; defining a groove by etching the first insulation layer; forming a lower electrode in the groove; recessing the lower electrode; forming a second insulation layer on the recessed lower electrode to fill the groove; etching the second insulation layer and to define a hole for exposing the lower electrode; forming a lower electrode contact in the hole; and forming a phase change layer and an upper electrode on the lower electrode contact. By manufacturing the phase change memory device in this manner, the interface between the lower electrode contact and a phase change layer can be defined in a stable manner, resulting in the uniformity of a programming circuit.

### CROSS-REFERENCE TO RELATED APPLICATIONS

The present application claims priority to Korean patent application number 10-2006-0113471 filed on Nov. 16, 2006, which is incorporated herein by reference in its entirety.

### BACKGROUND OF THE INVENTION

The present invention relates to a phase change memory device, and more particularly, to a phase change memory device in which a hole for a lower electrode contact is defined in a stable manner, and a method for manufacturing the same.

In general, memory devices are largely divided into a volatile RAM (random access memory), which loses inputted information when power is interrupted, and a non-volatile ROM (read-only memory), which can continuously maintain the stored state of inputted information even when power is interrupted. When considering volatile RAM, a DRAM (dynamic RAM) and an SRAM (static RAM) can be mentioned, and when considering non-volatile ROM, a flash memory device such as an EEPROM (electrically erasable and programmable ROM) can be mentioned.

As is well known in the art, while the DRAM is an excellent memory device, the DRAM must have high charge storing capacity, and to this end, since the surface area of an electrode must be increased, it is difficult to accomplish a high level of integration. Further, in the flash memory device, due to the fact that two gates are stacked on each other, a high operation voltage is required when compared to a source voltage. As a result, a separate booster circuit is needed to form the voltage necessary for write and delete operations, making it difficult to accomplish a high level of integration.

To improve upon the current memory devices, researches have been actively making an effort to develop a novel memory device which has a simple configuration and is capable of accomplishing a high level of integration while retaining the characteristics of the non-volatile memory device. A phase change memory device recently disclosed in the art is a product of this effort.

In the phase change memory device, a phase change, which occurs in a phase change layer interposed between a lower electrode and an upper electrode, from a crystalline state to an amorphous state is due to current flow between the lower electrode and the upper electrode The information stored in a cell is recognized by the medium of a difference in resistance between the crystalline state and the amorphous state.

In detail, in the phase change memory device, a chalcogenide layer, being a compound layer made of germanium (Ge), stibium (Sb) and tellurium (Te), is employed as a phase change layer. As a current is applied, the phase change layer undergoes a phase change by heat, that is, Joule heat, between the amorphous state and the crystalline state. Accordingly, in the phase change memory device, when considering the fact that the specific resistance of the phase change layer in the amorphous state is higher than the specific resistance of the phase change layer in the crystalline state, in a read mode, whether the information stored in a phase change cell has a logic value of ‘1’ or ‘0’ is determined by sensing the current flowing through the phase change layer.

Additionally, in the phase change memory device, since current flow greater than 1 mA is required in order to enable the phase change of the phase change layer, a contact area between the phase change layer and the electrode must be decreased so as to decrease the current required for enabling the phase change of the phase change layer.

FIG. 1 is a cross-sectional view illustrating a conventional phase change memory device.

Referring to FIG. 1, gates 101 are formed on a semiconductor substrate 100, and junction areas (not shown) are formed in the surface of the semiconductor substrate 100 on both sides of the gate 101. An interlayer dielectric 102 is formed on the overall surface of the semiconductor substrate 100 to cover the gates 101. A first contact plug 108a and a second contact plug 108b are respectively formed in the portions of the interlayer dielectric 102 that correspond to a phase change cell forming region and a ground line (Vss) forming region.

A first insulation layer 106 is formed on the interlayer dielectric 102. A lower electrode 110 is formed in the portion of the first insulation layer 106 which corresponds to the phase change cell forming region. The lower electrode 110 is formed to come into contact with the first contact plug 108a. A ground line 109 is formed in the portion of the first insulation layer 106 which corresponds to the ground line forming region. The ground line 109 is formed to come into contact with the second contact plug 108b.

A nitride layer 107 for preventing oxidation of the lower electrode 110 is formed on the first insulation layer 106 including the lower electrode 110 and the ground line 109. A second insulation layer 111 is formed on the nitride layer 107. A lower electrode contact 114 having the shape of a plug is formed in the portion of the second insulation layer 111, which corresponds to the phase change cell forming region, through a damascene process.

A phase change layer 116 and an upper electrode 118 are sequentially formed on a portion of the second insulation layer 111 to come into contact with the lower electrode contact 114.

However, in the conventional phase change memory device, when forming the lower electrode contact 114 through the damascene process the contact hole for forming the lower electrode contact 114 is likely to be non-uniformly defined, and therefore the lower electrode contact 114 cannot be stably formed. In further detail, in order to define the contact hole, the nitride layer 107 and the second insulation layer 111 are etched through the damascene process. At this time, because the second insulation layer comprises an oxide layer, as the nitride layer 107 and the oxide layer formed of different materials are etched, the contact hole is likely to be non-uniformly defined, making it difficult to stably form the lower electrode contact 114. As a result, due to the fact that the lower electrode contact 114 to come into contact with the phase change layer 116 cannot be stably formed, the uniformity of a programming current cannot be ensured, and the characteristics of the phase change memory device are likely to be degraded.

### SUMMARY OF THE INVENTION

Embodiments of the present invention are directed to a phase change memory device in which a hole for a lower electrode contact is defined in a stable manner, and a method for manufacturing the same.

In one aspect, a phase change memory device comprises a semiconductor substrate; an interlayer dielectric and a first insulation layer sequentially formed on the semiconductor substrate. The first insulation layer has a groove; a lower electrode formed in the groove to have a recessed shape; a nitride layer formed on the lower electrode to fill the groove; a lower electrode contact formed in the nitride layer to come into contact with the lower electrode; and a phase change layer and an upper electrode sequentially formed on the lower electrode contact.

The phase change memory device further comprises a contact plug formed in the interlayer dielectric to come into contact with the lower electrode.

The contact plug is formed integrally with the lower electrode.

A spacer is interposed between the nitride layer and the lower electrode layer so that the contact area can be decreased.

In another embodiment, a method for manufacturing a phase change memory device comprises the steps of forming a first insulation layer on a semiconductor substrate which has a plurality of phase change cell forming regions; defining a groove by etching the first insulation layer; forming a lower electrode in the groove; recessing the lower electrode; forming a second insulation layer on the recessed lower electrode to fill the groove; etching the second insulation layer and thereby defining a hole for exposing the lower electrode; forming a lower electrode contact in the hole; and forming a phase change layer and an upper electrode on the lower electrode contact.

The lower electrode is recessed through an etch back process.

The lower electrode is recessed in a manner such that the removed lower electrode is a thickness of 500˜1,500 Å from an upper end of the groove.

The second insulation layer comprises a nitride layer.

The hole is defined in such a way as to expose a center portion of the lower electrode.

After the step of defining the hole for exposing the lower electrode, the method further comprises the step of forming a spacer on a sidewall of the hole.

The phase change layer and the upper electrode are formed in a manner such that a plurality of phase change cells are connected with one another.

In still another embodiment, a method for manufacturing a phase change memory device comprises the steps of forming an interlayer dielectric on a semiconductor substrate which has a plurality of phase change cells; forming a first insulation layer on the interlayer dielectric; defining a groove by etching the first insulation layer; etching a portion of the interlayer dielectric which is exposed through the groove, thereby defining a contact hole for exposing the semiconductor substrate; forming a contact plug in the contact hole and a lower electrode in the groove; recessing the lower electrode; forming a second insulation layer on the recessed lower electrode to fill the groove; etching the second insulation layer and thereby defining a hole for exposing the lower electrode; forming a lower electrode contact in the hole; and forming a phase change layer and an upper electrode on the lower electrode contact.

After the step of forming the interlayer dielectric and before the step of forming the first insulation layer, the method further comprises the step of forming an etch stop layer on the interlayer dielectric.

The etch stop layer comprises a nitride layer.

The contact plug and the lower electrode are formed integrally with each other.

The lower electrode is recessed through an etch back process.

The lower electrode is recessed in a manner such that the removed lower electrode is a thickness of 500˜1,500 Å from an upper end of the groove.

The second insulation layer comprises a nitride layer.

The hole is defined in such a way as to expose a center portion of the lower electrode.

After the step of defining the hole for exposing the lower electrode, the method further comprises the step of forming a spacer on a sidewall of the hole.

### BRIEF DESCRIPTION OF THE DRAWINGS

FIG. 1 is a cross-sectional view illustrating a conventional phase change memory device.

FIGS. 2A and 2B are cross-sectional views each illustrating a phase change memory device in accordance with an embodiment of the present invention.

FIGS. 3A through 3G are cross-sectional views illustrating the process steps of a method for manufacturing a phase change memory device in accordance with another embodiment of the present invention.

FIG. 4 is a cross-sectional view illustrating a phase change memory device in accordance with another embodiment of the present invention.

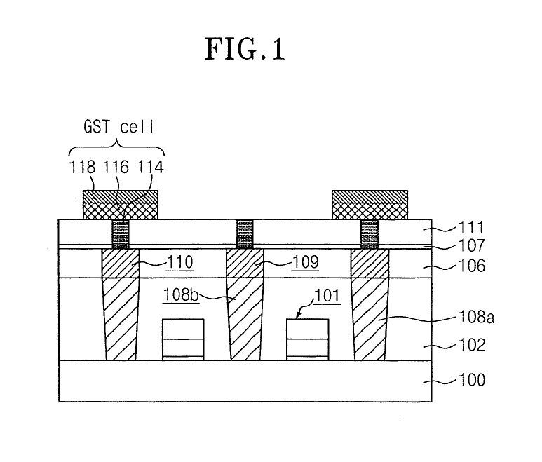

### DESCRIPTION OF SPECIFIC EMBODIMENTS

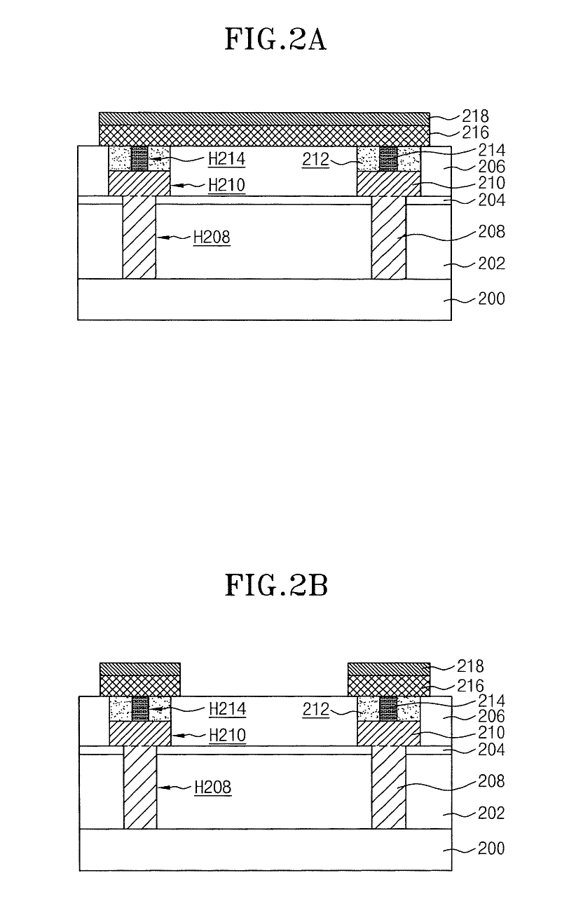

FIG. 2A is a cross-sectional view illustrating a phase change memory device in accordance with an embodiment of the present invention.

Referring to FIG. 2, a phase change memory device in accordance with an embodiment of the present invention includes a semiconductor substrate 200 having a plurality of phase change cell regions, an interlayer dielectric 202 having a contact hole H208 which exposes each phase change cell region, a first insulation layer 206 formed over the interlayer dielectric 202 and having a groove H210 which communicates with the contact hole H208, a contact plug 208 formed in the contact hole H208, a lower electrode 210 which a recessed shape formed in the groove H210, a second insulation layer 212 formed on the lower electrode 210 in the groove H210 and having a hole H214 which exposes the center portion of the lower electrode 210, a lower electrode contact 214 filled in the hole H214, and a phase change layer 216 and an upper electrode 218 sequentially formed on the lower electrode contact 214.

Here, a nitride layer 204 serving as an etch stop layer is additionally formed between the interlayer dielectric 202 and the first insulation layer 206. The contact plug 208 and the lower electrode 210 are formed integrally with each other. The second insulation layer 212 is composed of a nitride layer. Spacers (not shown) can be additionally formed on both sidewalls of the groove H210 so that the contact area between the lower electrode contact 214 and the phase change layer 216 can be decreased.

The phase change layer 216 and the upper electrode 218 are formed in a manner such that the plurality of phase change cells are connected with one another. Additionally, as shown in FIG. 2B, the phase change layer 216 and the upper electrode 218 can be formed in a manner such that they are located in each phase change cell.

Consequently, in the present invention, by uniformly forming the lower electrode contact 214 on the recessed lower electrode 210, the contact surface of the lower electrode contact 214 with the phase change layer 216 can be defined in a stable manner.

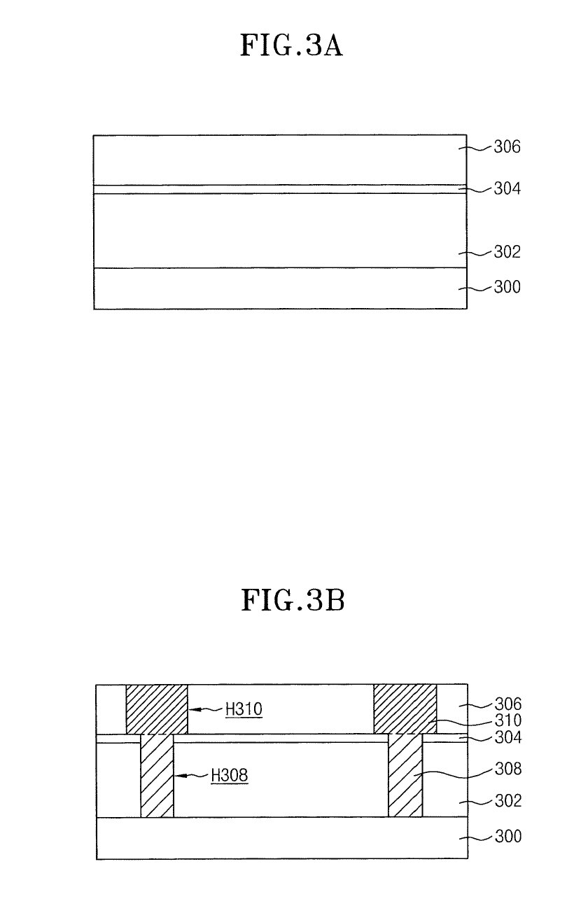

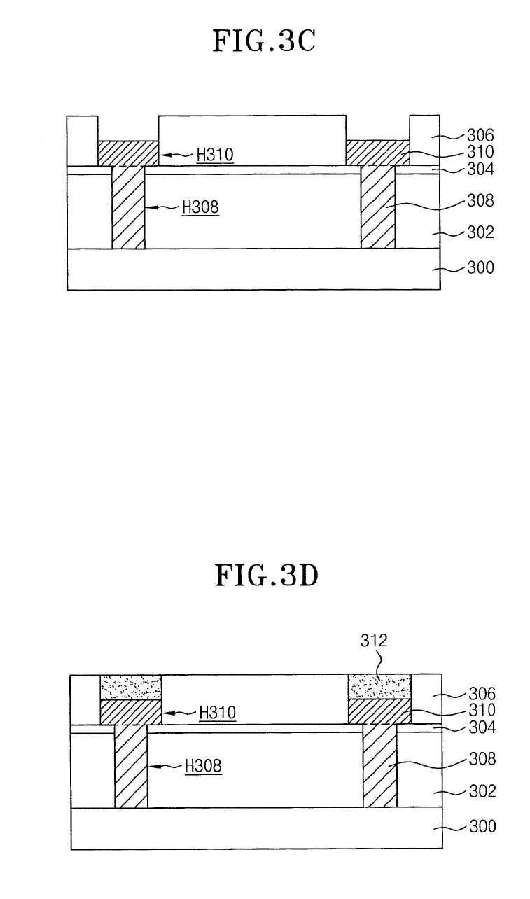

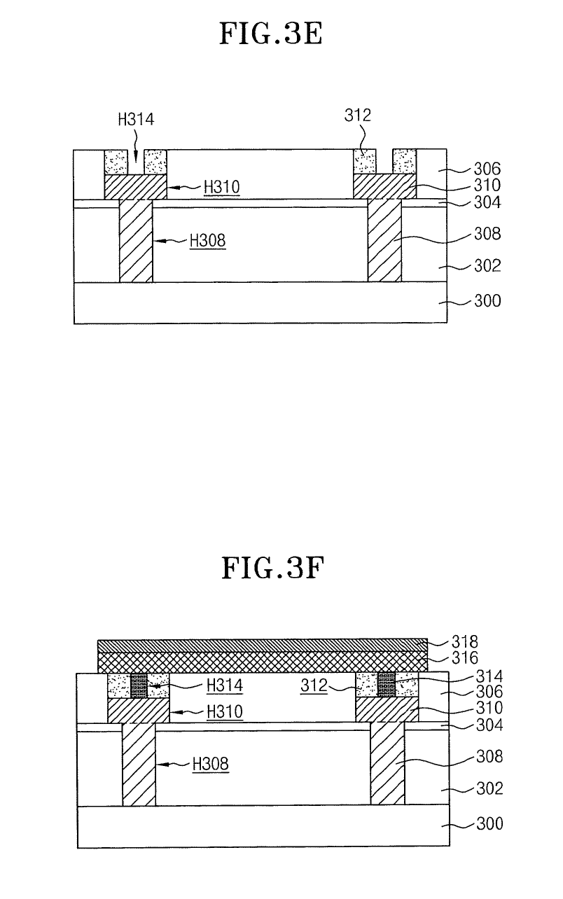

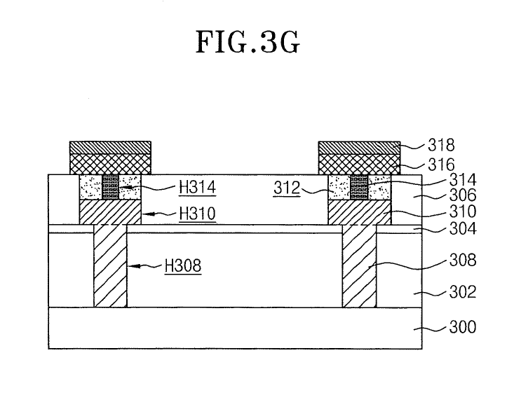

FIGS. 3A through 3G are cross-sectional views illustrating the process steps of a method for manufacturing a phase change memory device in accordance with another embodiment of the present invention.

Referring to FIG. 3A, an oxide layer-based interlayer dielectric 302 is formed on a semiconductor substrate 300 which has a plurality of phase change cell regions and is provided with transistors each composed of a gate (not shown) and source and drain regions (not shown). A nitride layer 304 is formed on the interlayer dielectric 302 to perform as an etch stop layer. After forming the nitride layer 304, a first insulation layer 306 is formed on the nitride layer 304.

Referring to FIG. 3B, according to a duel damascene process, by etching the first insulation layer 306 until the nitride layer 304 is exposed, a groove H310, which delimits a lower electrode forming region, is defined, and thereafter, by etching the interlayer dielectric 302 in such a way as to expose the phase change cell region, a contact hole H308, which delimits a contact plug forming region, is defined. A conductive layer is then deposited on the resultant substrate in such a way as to fill the contact hole H308 and the groove H310. After depositing this conductive layer, by CMPing (chemically and mechanically polishing) the conductive layer until the first insulation layer 306 is exposed, a contact plug 308 is formed in the contact hole H308, and a lower electrode 310 is formed in the groove H310. The contact plug 308 and the lower electrode 310 are formed integrally with each other by the dual damascene process.

Here, due to the fact that the contact plug 308 and the lower electrode 310 are formed through the dual damascene process, the resistance generated in the interface between the contact plug 308 and the lower electrode 310 can be decreased, and the voltage applied to the source and drain regions of the transistor can be increased.

Referring to FIG. 3C, the lower electrode 310 is recessed through an etch back process. The etch back process is conducted such that the lower electrode 310 is recessed by a thickness of 500˜1,500 Å from the upper end of the groove H310.

Referring to FIG. 3D, A nitride layer-based second insulation layer 312 is formed on the lower electrode 310 in the groove H310 in such a way as to fill the groove H310. After it is formed, the second insulation layer 312 is CMPed until the first insulation layer 306 is exposed.

Referring to FIG. 3E, by etching the second insulation layer 312, a hole H314, which exposes the center portion of the lower electrode 310, that is, delimits a lower electrode contact forming region, is defined. Here, in the present invention, when conducting an etching process to define the hole H314 for delimiting the lower electrode contact forming region, since only a single layer (the second insulation layer 312) is etched, the hole H314 can be defined uniformly.

In other words, in the conventional art, when conducting an etching process to define a hole in which a lower electrode contact is formed, since two layers made of different materials are etched, the hole is likely to be defined non-uniformly. Therefore, as the lower electrode contact is formed unstably, the contact surface of the lower electrode contact with a phase change layer is made unstable. In this regard, in the present invention, since the hole H314 is defined by etching only the single layer (the second insulation layer 312) the hole H314 can be defined uniformly, and as a result, a lower electrode contact can be stably formed in the hole H314 in a subsequent process. Therefore, in the present invention, the interface between the lower electrode contact and the phase change layer subsequently formed can be made stable, whereby the uniformity of a programming current can be ensured.

Meanwhile, while not shown in the drawings, spacers can be formed on both sidewalls of the hole H314 so that the size of the hole H314 can be decreased.

Referring to FIG. 3F, a conductive layer for a lower electrode contact is deposited in such a way as to fill the hole H314. By etching the conductive layer, a lower electrode contact 314 is formed in the hole H314. The lower electrode contact 314 is formed of a material which has low reactivity with the phase change layer subsequently formed. Preferably, the lower electrode contact 314 can be made of a titanium nitride layer (TiN layer), a titanium tungsten layer (TiW layer), or a titanium aluminum nitride layer (TiAlN layer). A phase changer material layer and a conductive layer for an upper electrode are deposited on the substrate including the lower electrode contact 314. The conductive layer for an upper electrode is formed of a material which has low reactivity with the phase change material layer. Preferably, the conductive layer for an upper electrode can be made of a titanium nitride layer (TiN layer), a titanium tungsten layer (TiW layer), or a titanium aluminum nitride layer (TiAlN layer).

By etching the conductive layer for an upper electrode and the phase change material layer, a phase change layer 316 and an upper electrode 318 are sequentially formed on the lower electrode contact 314.

Referring to FIG. 3G, the phase change layer 316 and the upper electrode 318 are formed in the shape of a pattern in each phase change cell region. The phase change layer 316 and the upper electrode 318 can be formed in a manner such that the plurality of phase change cells are connected with one another. When the phase change layer 316 and the upper electrode 318 are formed in this manner, it is possible to solve the problem caused by the fact that as the size of the cell is decreased, due to the etch loss caused on the edge of the phase change material layer when etching the phase change material layer, the composition of the phase change layer 316 varies in an initial stage.

Thereafter, while not shown in the drawings, by sequentially implementing a series of subsequent well-known processes, the manufacture of a phase change memory device according to the present invention is completed.

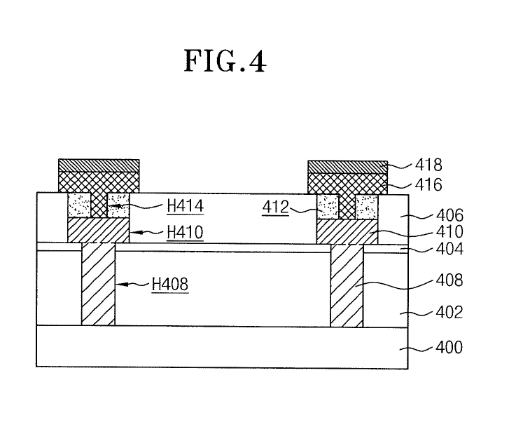

In the above embodiment, after forming the lower electrode contact 314 in the hole H314, the phase change layer 316 and the upper electrode 318 are formed on the lower electrode contact 314. However, according to another embodiment of the present invention as shown in FIG. 4, it can be envisaged that, without forming a lower electrode contact in a hole H414, a phase change layer 416 and an upper electrode 418 can be sequentially formed on a nitride layer 412 including the hole H414.

In FIG. 4, the unexplained reference numerals designate: 400 a semiconductor substrate, 402 an interlayer dielectric, 404 a nitride layer, 406 a first insulation layer, 408 a contact plug, and 410 a lower electrode. Also, the unexplained reference symbol H410 designates a groove which delimits a lower electrode forming region, and H408 a contact hole which delimits a contact plug forming region.

As is apparent from the above description, in the present invention, when conducting an etching process for defining a hole for delimiting a lower electrode contact forming region, since a single layer (rather than multiple layers) is etched, the hole can be uniformly defined. Accordingly, a lower electrode contact can be stably formed in the hole. Due to this fact, because the interface between the lower electrode contact and a phase change layer can be defined in a stable manner, the uniformity of a programming current can be ensured.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A phase change memory device comprising:
a semiconductor substrate;
an interlayer dielectric and a first insulation layer sequentially formed on the semiconductor substrate, the first insulation layer having a groove;
a lower electrode having a recessed shape formed in a lower portion of the groove;
a nitride layer formed on the lower electrode filling a remaining upper portion of the groove;
a lower electrode contact formed in the nitride layer, the lower electrode contact contacting the lower electrode; and
a phase change layer and an upper electrode sequentially formed on the lower electrode contact.

2. The phase change memory device according to claim 1, further comprising:
a contact plug formed in the interlayer dielectric to come into contact with the lower electrode.

3. The phase change memory device according to claim 2, wherein the contact plug is formed integrally with the lower electrode.

4. The phase change memory device according to claim 1, further comprising:
a spacer interposed between the nitride layer and the lower electrode contact.

5. A method for manufacturing a phase change memory device, comprising the steps of:
forming a first insulation layer on a semiconductor substrate having a plurality of phase change cell forming regions;
defining a groove by etching the first insulation layer;
forming a lower electrode in the groove;
recessing the lower electrode;
forming a second insulation layer on the recessed lower electrode to fill the groove;
etching the second insulation layer so a hole for exposing the lower electrode is formed;
forming a lower electrode contact in the hole; and
forming a phase change layer and an upper electrode on the lower electrode contact.

6. The method according to claim 5, wherein the lower electrode is recessed through an etch back process.

7. The method according to claim 5, wherein the lower electrode is recessed such that a portion of the lower electrode is removed by a thickness of 500˜1,500 Å from an upper end of the groove.

8. The method according to claim 5, wherein the second insulation layer comprises a nitride layer.

9. The method according to claim 5, wherein the hole is defined to expose a center portion of the lower electrode.

10. The method according to claim 5, further comprising the step of:
after defining the hole for exposing the lower electrode, forming a spacer on a sidewall of the hole.

11. The method according to claim 5, wherein the phase change layer and the upper electrode are formed in a manner such that a plurality of phase change cells formed on the plurality of phase change cell forming regions are connected with one another.

12. A method for manufacturing a phase change memory device, comprising the steps of:
forming an interlayer dielectric on a semiconductor substrate having a plurality of phase change cells;
forming a first insulation layer on the interlayer dielectric;
defining a groove exposing the interlayer dielectric by etching the first insulation layer;
etching a portion of the interlayer dielectric which is exposed through the groove, and by etching the portion defining a contact hole for exposing the semiconductor substrate;
forming a contact plug in the contact hole and a lower electrode in the groove;
recessing the lower electrode;
forming a second insulation layer on the recessed lower electrode to fill the groove;
etching the second insulation layer to define a hole for exposing the lower electrode;
forming a lower electrode contact in the hole; and
forming a phase change layer and an upper electrode on the lower electrode contact.

13. The method according to claim 12, further comprising the step of:
after the step of forming the interlayer dielectric and before the step of forming the first insulation layer, forming an etch stop layer on the interlayer dielectric.

14. The method according to claim 13, wherein the etch stop layer comprises a nitride layer.

15. The method according to claim 12, wherein the contact plug and the lower electrode are formed integrally with each other.

16. The method according to claim 12, wherein the lower electrode is recessed through an etch back process.

17. The method according to claim 12, wherein the lower electrode is recessed such that a portion of the lower electrode is removed by a thickness of 500˜1,500 Å from an upper end of the groove.

18. The method according to claim 12, wherein the second insulation layer comprises a nitride layer.

19. The method according to claim 12, wherein the hole is defined in such a way as to expose a center portion of the lower electrode.

20. The method according to claim 12, further comprising the step of:
after the step of defining the hole for exposing the lower electrode, forming a spacer on a sidewall of the hole.
